(19) United States
(12) Patent Application Publication
(10) Pub. No.: US 2010/0032196 A1
(43) Pub. Date: Feb. 11, 2010

(54) MULTILAYER WIRING BOARD, SEMICONDUCTOR PACKAGE AND METHOD OF MANUFACTURING THE SAME

(75) Inventors: Kentaro KANEKO, Nagano-shi (JP); Kazuhiro Kobayashi, Nagano-shi (JP); Yoshiki Okushima, Nagano-shi (JP); Kotaro Kodani, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/537,391

(22) Filed: Aug. 7, 2009

(30) Foreign Application Priority Data
Aug. 11, 2008 (JP) 2008-207379

(51) Int. Cl. H05K 1/16; H05K 1/11; B32B 37/00

(52) U.S. Cl. 174/260; 174/262; 156/60

(57) ABSTRACT

In a multilayer wiring board having a wiring layer, a pad, an insulating layer provided between the wiring layer and the pad, and a plurality of connecting vias provided on the insulating layer and connecting the wiring layer to the pad, the connecting vias are provided on a peripheral edge of the pad.

This application claims priority to Japanese Patent Application No. 2008-207379, filed Aug. 11, 2008, in the Japanese Patent Office. The Japanese Patent Application No. 2008-207379 is incorporated by reference in its entirety.

### TECHNICAL FIELD

The present disclosure relates to a multilayer wiring board, a semiconductor package and a method of manufacturing the same.

### RELATED ART

With high density mounting of a semiconductor device, a “coreless board” having a small thickness is used in a high density multilayer wiring board to be utilized in a semiconductor package having a semiconductor chip mounted thereon. The coreless board is a multilayer wiring board including no core layer having a reinforcing and supporting function of a board body which has been described in Patent Document 1, for example.

FIG. 1 is a schematic view showing a coreless board 1. A manufacture is carried out by a method of performing a buildup method through a repetitively sequential stack of a solder resist 3, an electrode 4, an insulating layer 5, a connecting via 6 and a wiring layer 7, and the insulating layer 5, the connecting via 6 and the wiring layer 7 on a support board 2 and then removing the support board 2, for example. In the coreless board, a function of a rigidity against a warpage or a deformation of the board is not sufficiently fulfilled in some cases differently from a board having a core layer of the related art. For example, there is a drawback that peeling or a crack in the vicinity of a pad corner is caused over an insulating layer in an interface portion in which a pad is bonded to the insulating layer due to a deformation of the whole board or a generation of an internal stress. In order to prevent the peeling and the crack in the vicinity of the pad of the coreless board, for example, there has been disclosed a technique such as a pad structure in Patent Document 2.

FIG. 2 shows an example of a structure of a pad according to the related art based on description of FIGS. 1 and 2 in the Patent Document 2. A pad 21 is formed in such a shape that a wall surface conductor portion 24 to be formed along a wall portion 23 of an opening of an insulating layer 22 is extended in a direction x of a wiring board in order to increase a bonding area of the pad 21 and the insulating layer 22. By the shape, an internal stress is distributed to prevent the crack from being caused.

[Patent Document 1] JP-A-2007-13092 Publication

[Patent Document 2] JP-A-2005-244108 Publication

In the wiring board having the “wall surface conductor portion” described in the Patent Document 2, there is a problem in that the number of wiring forming steps is increased in order to obtain a pad for increasing the bonding area. In respect of the structure, moreover, there is not a reliably fixed connecting function for preventing peeling of the pad and the insulating layer with respect to a stacking direction when an external force for generating a deformation or bending acts on the board. Therefore, there is generated a situation in which the peeling or the crack cannot be eliminated sufficiently.

### SUMMARY

Exemplary embodiments of the present invention provide a multilayer wiring board, a semiconductor package and a method of manufacturing the same in which it is possible to effectively prevent peeling or a crack from being caused without increasing the number of steps in a multilayer wiring board.

Exemplary embodiments of the invention provides a multilayer wiring board including a wiring layer, a pad, an insulating layer provided between the wiring layer and the pad, and a plurality of connecting vias provided on the insulating layer and connecting the wiring layer to the pad, wherein the connecting vias are provided on a peripheral edge of the pad.

Moreover, exemplary embodiments of the invention provides a multilayer wiring board including a wiring layer, a pad, an insulating layer provided between the wiring layer and the pad, and a ring-shaped connecting body provided on the insulating layer and connecting the wiring layer to the pad, wherein the ring-shaped connecting body is provided on a peripheral edge of the pad.

Furthermore, exemplary embodiments of the invention provides a method of manufacturing a multilayer wiring board having a wiring layer, a pad, an insulating layer provided between the wiring layer and the pad, and a plurality of connecting vias provided on the insulating layer and connecting the wiring layer to the pad, the method including the steps of forming the pad on a support board, forming the insulating layer, forming, in the insulating layer, a space for the connecting vias to be connected at a peripheral edge of the pad, forming the connecting vias, forming the wiring layer through a connection to the connecting vias, sequentially stacking the insulating layer and the wiring layer into a multilayer, and removing the support board.

Moreover, exemplary embodiments of the invention provides a method of manufacturing a multilayer wiring board having a wiring layer, a pad, an insulating layer provided between the wiring layer and the pad, and a ring-shaped connecting body provided on the insulating layer and connecting the wiring layer to the pad, the method including the steps of forming the pad on a support board, forming the insulating layer, forming, in the insulating layer, a space for the ring-shaped connecting body to be connected at a peripheral edge of the pad, forming the ring-shaped connecting body, forming the wiring layer through a connection to the ring-shaped connecting body, sequentially stacking the insulating layer and the wiring layer into a multilayer, and removing the support board.

Furthermore, exemplary embodiments of the invention provides a method of manufacturing a multilayer wiring board having a wiring layer, a pad, an insulating layer provided between the wiring layer and the pad, and a ring-shaped connecting body and a connecting via which are provided on the insulating layer and connect the wiring layer to the pad, the method including the steps of forming the pad on a support board, forming the insulating layer, forming, in the insulating layer, a space for the ring-shaped connecting body to be connected at a peripheral edge of the pad and a space for the connecting via provided at an inside of the ring-shaped connecting body, forming the ring-shaped connecting body and the connecting via at the same time, forming the wiring layer by connecting the ring-shaped connecting body and the connecting via, sequentially stacking the insulating layer and the wiring layer into a multilayer, and removing the support board.

According to the invention, it is possible to effectively prevent peeling or a crack from being caused without increasing the number of the steps in the multilayer wiring board.

Other features and advantages may be apparent from the following detailed description, the accompanying drawings and the claims.

### BRIEF DESCRIPTION OF THE DRAWINGS

FIG. 1 is a view illustrating an outline of a coreless board 1,

FIG. 2 is a view illustrating a structure of a pad according to the related art,

FIG. 3A is a view illustrating a multilayer wiring board 30 and respective elements thereof according to a first embodiment of the invention,

FIG. 3B is a view illustrating a section taken along a cutting line C-C in FIG. 3A according to the first embodiment of the invention,

FIGS. 3C to 3H are views illustrating a section taken along the cutting line C-C in FIG. 3A according to a variant 1 of the first embodiment in accordance with the invention,

FIG. 4 is a view illustrating a multilayer wiring board according to a variant 2 of the first embodiment in accordance with the invention,

FIG. 5 is a view illustrating a structure in the case in which a surface of a pad is not flat according to the related art,

FIG. 6A is a view illustrating a multilayer wiring board 60 and respective elements thereof according to a second embodiment of the invention,

FIG. 6B is a view illustrating a section taken along a cutting line D-D in FIG. 6A according to the second embodiment of the invention,

FIG. 6C is a view illustrating a section taken along the cutting line D-D in FIG. 6A according to a variant of the second embodiment in accordance with the invention,

FIG. 7 is a view illustrating a semiconductor package 70 provided with a semiconductor chip according to a third embodiment of the invention,

FIG. 8A is a view illustrating another semiconductor package 80 provided with a semiconductor device according to the third embodiment of the invention,

FIG. 8B is a view illustrating an apparatus 300 in a state in which a multilayer wiring board 302 having a semiconductor chip 301 mounted thereon is connected to a mother board 303 according to a fourth embodiment of the invention,

FIG. 9 is a flowchart illustrating a flow of a manufacture of a multilayer wiring board according to a fifth embodiment of the invention,

FIGS. 10A to 10F are views illustrating a state of a middle step for the manufacture of the multilayer wiring board according to the fifth embodiment of the invention,

FIG. 11 is a flowchart illustrating a flow of a manufacture of a multilayer wiring board according to a sixth embodiment of the invention,

FIGS. 12A to 12D are views illustrating a state of a middle step for the manufacture of the multilayer wiring board according to the sixth embodiment of the invention, and FIGS. 13A and 13B are views illustrating a multilayer wiring board according to a variant of the sixth embodiment in accordance with the invention.

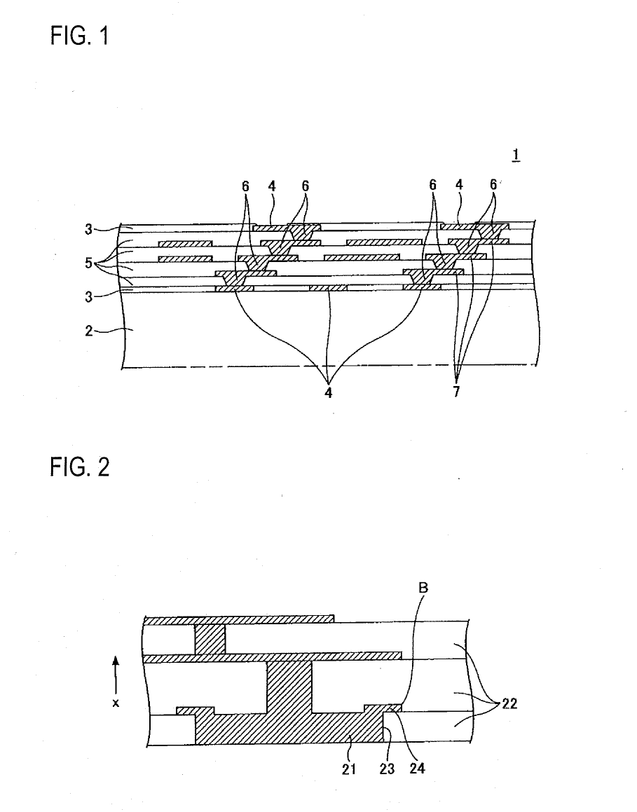

### DETAILED DESCRIPTION

The best mode for carrying out the invention will be described below with reference to the drawings.

### First Embodiment

A first embodiment according to the invention illustrates a multilayer wiring board having a structure in which six connecting vias are disposed at an equal interval on a peripheral edge of a pad.

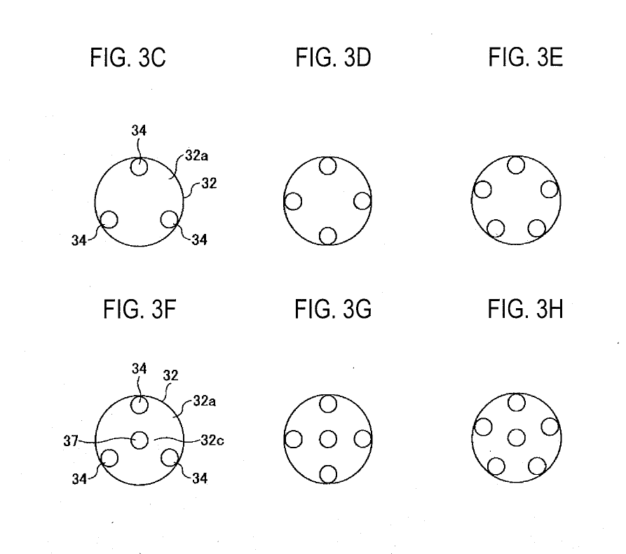

FIG. 3A is a view illustrating a multilayer wiring board 30 and respective elements thereof according to the first embodiment of invention. The respective elements are constituted by a wiring layer 31, a pad 32, an insulating layer 33, a plurality of connecting vias 34 provided on the insulating layer 33 and connecting the wiring layer 31 to the pad 32, and a plated layer 35 on a surface of the pad 32 at an opposite side to the connecting vias 34. A metal bump 36 for connecting a semiconductor chip is also shown.

### (Reason for Nonoccurrence of Stress Concentration or Peeling in Insulating Layer)

By the structure shown in FIG. 3A, the connecting vias 34 occupy a region of a peripheral edge 32a of the pad 32 through a connection, resulting in a decrease in an area of a region of the peripheral edge 32a in which the insulating layer 33 is to originally cause an internal deformation or peeling. Therefore, it is possible to prevent a stress concentration, peeling or a crack in the insulating layer 33 in the vicinity of a corner portion 32b of the pad 32. The “peripheral edge” 32a in FIG. 3A indicates a region provided on just an inner side of an outer periphery of a surface of the pad 32.

Moreover, the structure in FIG. 3A indicates that a fixed connection in a stacking direction (an x direction) of the pad 32 and the insulating layer 33 in FIG. 3A produces such an advantage as to prevent a deformation against an external force. The pad 32 is bonded through the connecting vias 34 and is coupled to the wiring layer 31 to be one of stacked elements at the peripheral edge 32a. The wiring layer 31, the pad 32 and the insulating layer 33 for filling a space therebetween are integrated and fixedly connected in the stacking direction. By the fixed connecting structure in the stacking direction, also when an external force to cause bending or a warpage acts on the pad 32 and the insulating layer 33, the deformation can be prevented more effectively as compared with a related-art structure.

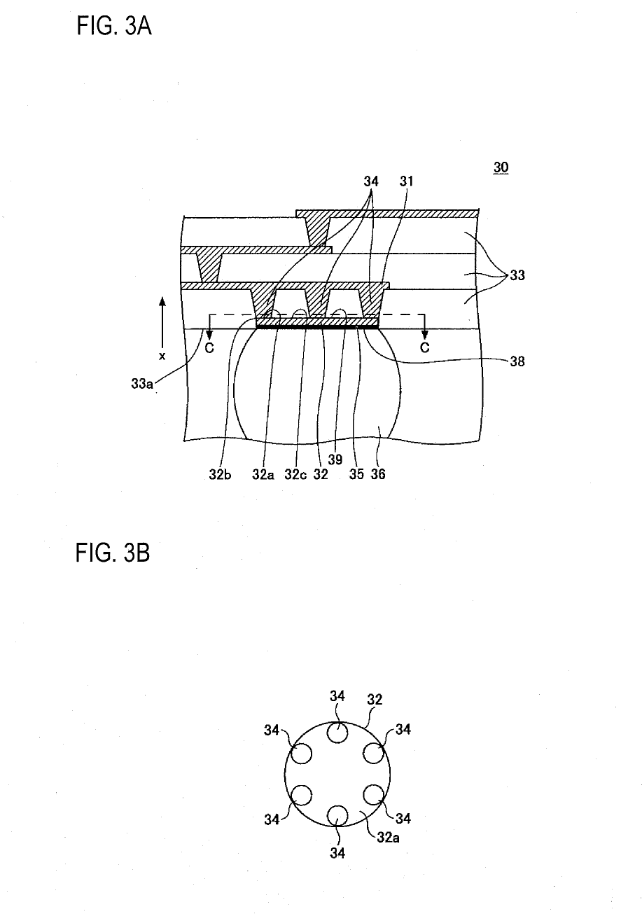

A structure for connecting a pad to an insulating layer in a related-art multilayer wiring board has no fixed connecting function in the stacking direction (the x direction shown in FIG. 2) other than bonding of the surfaces of the pad 21 and the insulating layer 22 as seen in the vicinity B of a corner portion of the pad 21 in the structure of FIG. 2 (based on the example described in the Patent Document 2 (JP-A-2005-244108 Publication)), for example. Accordingly, there is a tendency that peeling is easily caused over a bonded surface by an external deforming action.

According to the invention, however, a connecting strength in the stacking direction is reliably maintained and peeling of the insulating layer or a crack is not caused over an interface of a peripheral edge of the pad also in the case in which such an external force as to cause bending or a warpage acts by the fixed connecting structure in the stacking direction other than the bonding structure of the surfaces. According to the invention, moreover, a step of providing a layer such as the wall surface conductor portion 24 in FIG. 2 according to the related-art example is not required but a plurality of vias can be formed at the same time in the related-art via forming step. In a manufacture of the multilayer wiring board, therefore, it is possible to effectively prevent the peeling or the crack from being caused without increasing the number of steps.

### (Shape of Via)

In order to bond the connecting via to the peripheral edge of the pad having a very small limited area with high precision, it is effective that a section of the connecting via 34 at a connecting side to the pad 32 shown in FIG. 3A takes a thin shape, for example. Referring to the shape of the connecting via, a multilayer wiring board taking such a taper shape that a sectional area on a wiring layer side is larger than a sectional area on a pad side can be formed by a method of manufacturing a coreless board (which will be described below in a third embodiment), for example. The section of the connecting via usually takes a circular shape and a typical dimension of the section is φ65 to 75 μm on the wiring layer side and is φ55 to 65 μm on the pad side. Examples of an outside diameter of the pad is φ100 to 120 μm in the case in which mounting of a semiconductor chip is intended and is φ300 to 700 μm in the case in which mounting of other semiconductor devices is intended.

### (Arrangement of Connecting Via)

FIG. 3B is a view illustrating a section taken along a cutting line C-C in FIG. 3A. Six connecting vias 34 are disposed at an equal interval and are connected to the peripheral edge 32a of the pad 32. It is desirable that the connecting vias 34 should be provided on the peripheral edge 32a of the pad 32 at an equal interval in order to cause a stress load to be uniform against an external deformation.

Referring to the number of the connecting vias to be provided on the peripheral edge of the pad or the inner region of the peripheral edge and an arranging configuration, it is possible to properly select an increase/decrease or a change in a position depending on design data, for example, an electrical characteristic of a whole multilayer wiring board, the number of stacked layers, an insulating material and a wiring layer.

### (Flatness of Pad Surface)

In the invention, referring to the surface of the pad, a surface at an opposite side to the side where the via or the insulating layer is provided is flat.

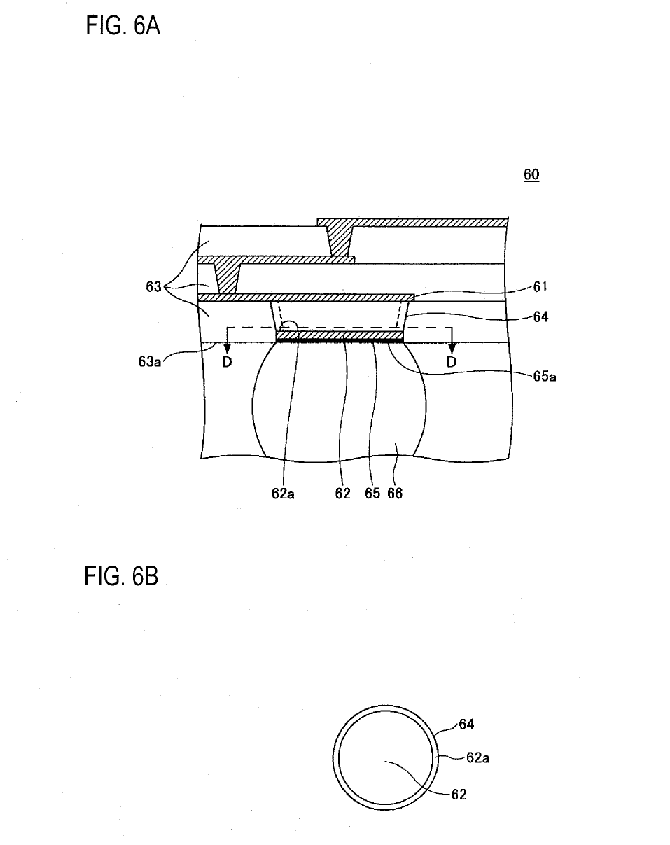

A surface 38 of the pad 32 in FIG. 3A takes a flat shape without an influence of a connecting state to the connecting via 34 in a back face 39. For example, in case of a method of manufacturing a coreless board, a pad is formed on a flat support board. Therefore, the surface of the pad can be flat. On the other hand, in a stacked board 50 having a core layer shown in FIG. 5 in which a stack and plating are sequentially carried out simply from the core layer side, a surface 51 of a pad is not flat. More specifically, a via takes such a shape that a sectional area is increased toward a surface at an opposite side to the core layer, and a hole space 52 is generated in the pad itself in the case in which a position of a connecting via is the same as a position of the pad 51 on the surface. In some cases in which the pad itself has the hole, a crack is caused by a stress concentration in an edge portion 53 of the hole when an external force acts in the vicinity of the pad. On the other hand, in the pad according to the invention, the flatness of the surface is ensured and there is no fear that the crack might be caused.

### Variant 1 of First Embodiment

In a variant 1 of the first embodiment according to the invention, the number and arrangement of connecting vias is changed.

The drawings in FIGS. 3C to 3E illustrate arrangements of three, four and five connecting vias 34 provided on the peripheral edge 32a of the pad 32 at equal intervals, respectively.

The drawings in FIGS. 3F to 3H illustrate that a connecting via 37 is also provided in a region 32c at an inside of the peripheral edge 32a of the pad 32 in addition to the three, four and five connecting vias 34 provided on the peripheral edge 32a of the pad 32 at the equal intervals. Although the connecting via 37 in each drawing is provided on a center point of the pad 32, it is possible to properly select an increase/decrease of a number or a change in a position depending on design data of the whole multilayer wiring board.

### Variant 2 of First Embodiment

A variant 2 of the first embodiment according to the invention illustrates a multilayer wiring board in which a position in a stacking direction of an exposed surface of the pad is set onto an inside of a stack from a surface of the multilayer wiring board.

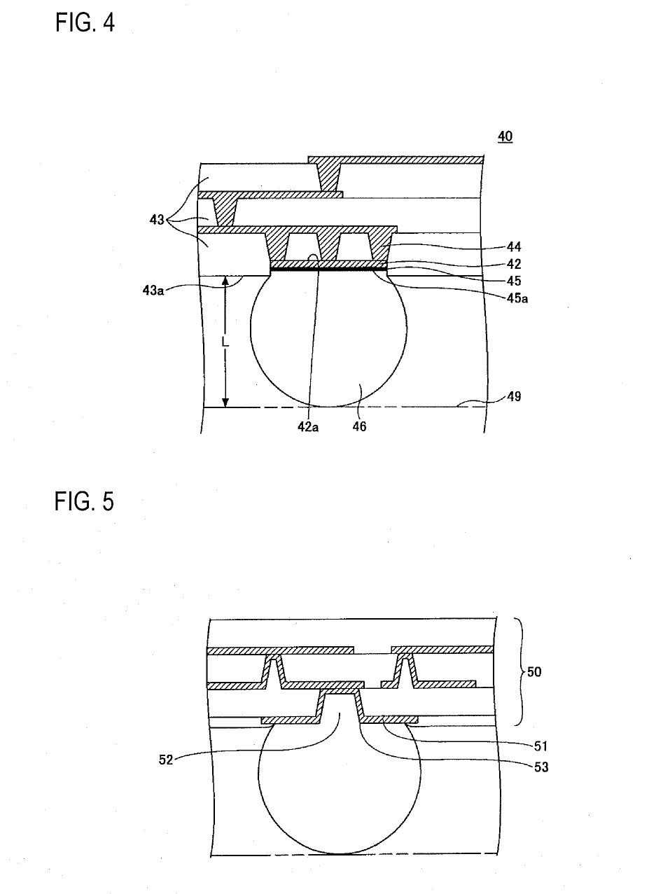

FIG. 4 is a view illustrating a multilayer wiring board 40 in which a surface 45a of a pad 42 is positioned on an inner layer of the multilayer wiring board from a position of a surface 43a of an insulating layer 43. A metal bump 46 is provided through a plated layer 45 on a surface of the pad 42 at an opposite side to a surface on which a connecting via 44 is provided, and a semiconductor chip or a semiconductor device 49 is mounted thereon so that a semiconductor package is formed. A thickness of the semiconductor package is to be minimized in order to reduce a size of a product. In order to minimize a height L of the metal bump 46, therefore, a position of the surface 45a of the pad 42 is set to an inner layer side of the surface 43a of the insulating layer 43. Consequently, it is possible to maintain a strength without changing the thickness of the metal bump 46. A manufacturing method can be carried out by utilizing a pad forming step in a manufacture of a coreless board as shown in an “electrode height regulating layer” which will be described below (a stage of (5), a fifth embodiment), for example.

In the case in which the height L of the metal bump 46 is not strictly restricted, moreover, it is possible to cause the surface 45a of the pad 42 to be on the level with the surface 43a of the insulating layer 43. Furthermore, it is possible to protrude the pad from the surface of the insulating layer, thereby increasing their bonding area to enhance a bonding strength. A method of manufacturing the protrusion of the pad can be carried out by forming a concave portion in a corresponding position of the pad in a support board in the manufacture of the coreless board, for example.

### Second Embodiment

A second embodiment according to the invention illustrates a multilayer wiring board having a structure in which a ring-shaped connecting body is provided in a peripheral edge portion of a pad.

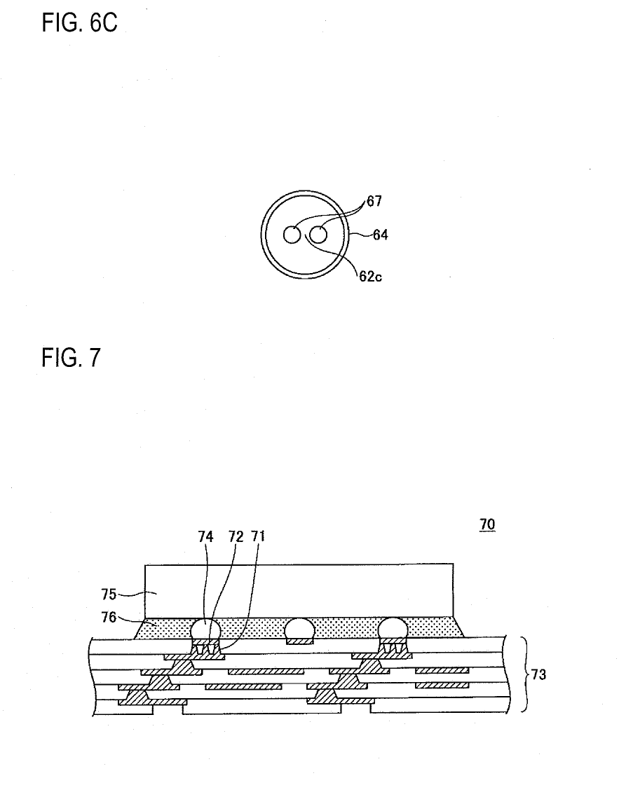

FIG. 6A is a view illustrating a multilayer wiring board 60 and respective elements thereof according to the second embodiment of the invention. The respective elements are constituted by a wiring layer 61, a pad 62, an insulating layer 63, a ring-shaped connecting body 64 provided on the insulating layer 63 and connecting the wiring layer 61 to the pad 62, and a plated layer 65 on a surface of the pad 62 at an opposite side to the ring-shaped connecting body 64. A metal bump 66 for connecting a semiconductor chip is also shown.

In the structure shown in FIG. 6A, the ring-shaped connecting body 64 is connected to the pad 62 in a region of a peripheral edge 62a thereof and occupies the region of the peripheral edge 62a. Accordingly, there is no place corresponding to a region in the vicinity of a corner portion of the pad 62 which has been occupied by the insulating layer 63 in the related art. Referring to the insulating layer 63, therefore, it is possible to prevent a stress concentration, peeling or a crack which has been caused in the vicinity of the corner portion in the related art.

FIG. 6A illustrates a state in which a surface 65a of the pad 62 at the metal bump 66 side is formed on the level with a surface 63a of the insulating layer 63 of the multilayer wiring board 60. In the same manner as in the positional relationship between the surface 45a of the pad 42 and the surface 43a of the insulating layer 43 shown in FIG. 4, however, the surface 65a of the pad 62 at the metal bump 66 side may be provided in a concave position on an inside of the multilayer wiring board 60 from the position of the surface 63a of the insulating layer 63.

FIG. 6B is a view illustrating a section taken along a cutting line D-D in FIG. 6A. There is shown a state in which the ring-shaped connecting body 64 is provided in the region of the peripheral edge 62a of the pad 62.

### Variant of Second Embodiment

FIG. 6C is a view illustrating a state in which two connecting vias 67 are provided in an inner region 62c of the peripheral edge of the pad 62 in addition to the ring-shaped connecting body 64 as a position in a sectional view taken along the cutting line D-D in FIG. 6A. Referring to the number and arranging configuration of the connecting vias or an arranging configuration of the ring-shaped connecting body, it is possible to properly select an increase/decrease or a change in a position depending on design data, for example, an electrical characteristic of a whole multilayer wiring board, the number of stacked layers, an insulating material and a wiring layer.

### Third Embodiment

A third embodiment according to the invention illustrates a semiconductor package in which a semiconductor chip or a semiconductor device is provided on a multilayer wiring board having a plurality of connecting vias disposed on a peripheral edge of a pad.

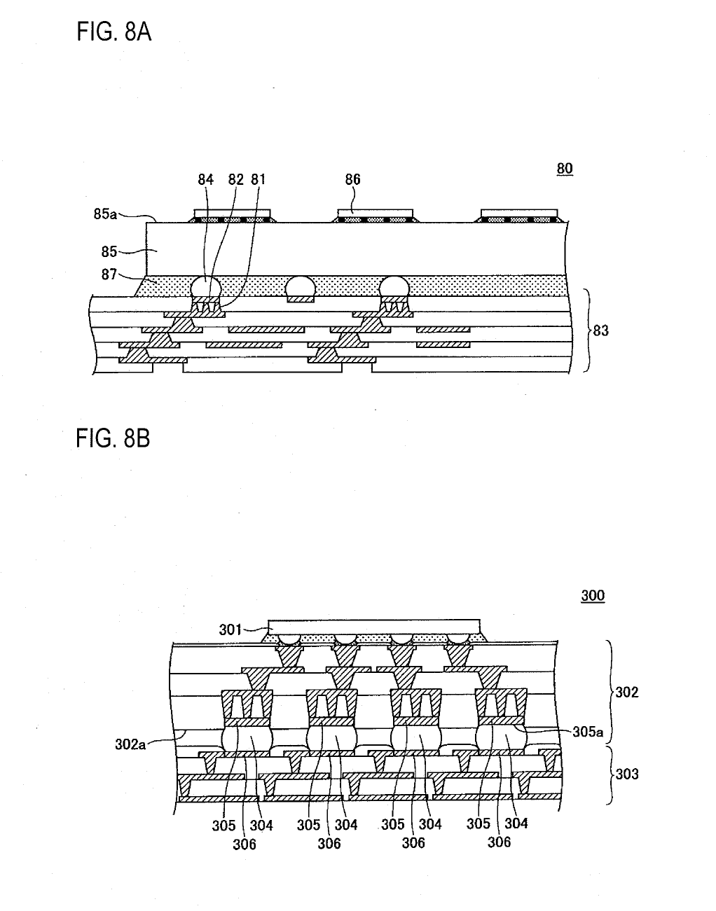

FIG. 7 is a view illustrating a semiconductor package 70 according to the third embodiment of the invention. The semiconductor package 70 has a semiconductor chip 75 which is electrically and mechanically connected through a metal bump 74 to a multilayer wiring board 73 in which a plurality of connecting vias 71 is provided on a peripheral edge of a pad 72. A gap between the semiconductor chip 75 and the multilayer wiring board 73 is sealed with a sealing resin 76. An outside diameter of the pad 72 is φ100 to 120 μm.

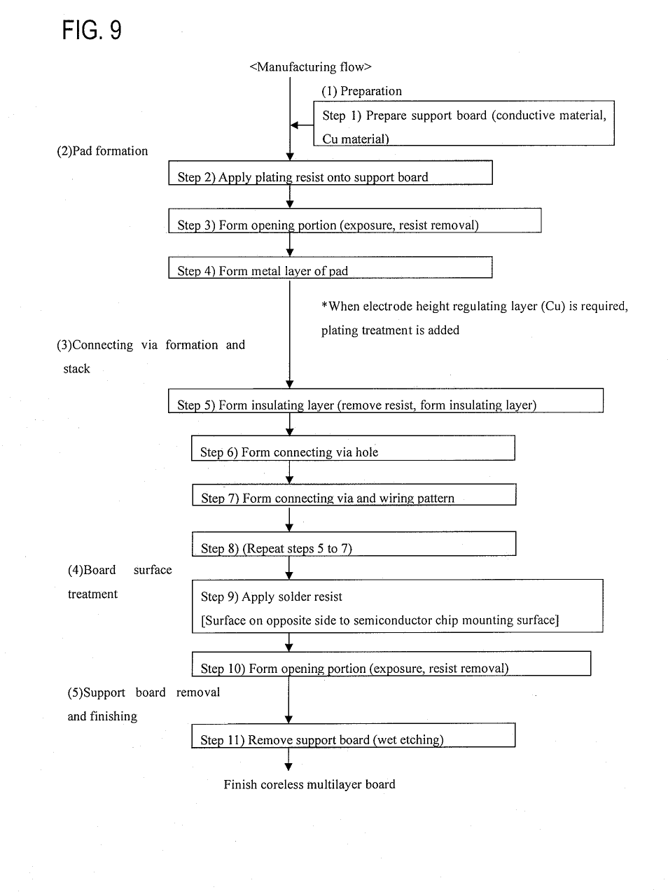

FIG. 8A is a view illustrating another semiconductor package 80 in which a semiconductor device 85 is provided. The semiconductor package 80 has the semiconductor device 85 which is electrically and mechanically connected through a metal bump 84 to a multilayer wiring board 83 in which a plurality of connecting vias 81 is provided on a peripheral edge of a pad 82. In the semiconductor device 85, a semiconductor chip 86 is mounted through flip chip bonding on a surface 85a at an opposite side to an opposed surface to the multilayer wiring board 83. A gap between the semiconductor device 85 and the multilayer wiring board 83 is sealed with a sealing resin 87. An outside diameter of the pad 82 is φ300 to 700 μm.

FIGS. 7 and 8A illustrate a state in which the surface of the pad at the metal bump side is formed on the level with the surface of the insulating layer of the multilayer wiring board. In the same manner as in the positional relationship between the surface 45a of the pad 42 and the surface 43a of the insulating layer 43 shown in FIG. 4, however, the surface of the pad at the metal bump side may be provided in a concave position on an inside of the multilayer wiring board from the position of the surface of the insulating layer in the multilayer wiring board.

### Fourth Embodiment

A fourth embodiment according to the invention illustrates an apparatus in a state in which a multilayer wiring board having a plurality of connecting vias provided on a peripheral edge of a pad and a mother board are connected to each other. The pad according to the invention is not restricted to a use in the case in which the multilayer wiring board has a semiconductor-chip or a semiconductor device mounted thereon but can be used as an external connecting terminal also in the case in which the multilayer wiring board is connected to the mother board or another mounting board.

FIG. 8B is a view illustrating an apparatus 300 in a state in which a multilayer wiring board 302 having a semiconductor chip 301 mounted thereon is connected to a mother board 303 through a metal bump 304 according to the fourth embodiment of the invention. An external connecting terminal 305 and a connecting terminal 306 of the mother board 303 are connected to each other through the metal bump 304. In the example, the multilayer wiring board 302 having the semiconductor chip 301 mounted thereon takes a configuration of BGA (Ball Grid Array).

FIG. 8B illustrates a state in which a surface 305a of the external connecting terminal 305 at the metal bump 304 side is provided in a concave position at an inside of a surface 302a of an insulating layer of the multilayer wiring board 302. In the same manner as in the positional relationship between the surface 38 of the pad 32 and the surface 33a of the insulating layer 33 of the multilayer wiring board 30 shown in FIG. 3A, however, the surface 305a of the external connecting terminal 305 at the metal bump 304 side may be provided in a position on the level with the surface 302a of the insulating layer of the multilayer wiring board 302.

### Fifth Embodiment

A fifth embodiment according to the invention illustrates a method of manufacturing a multilayer wiring board having a structure of a coreless board in which a plurality of connecting vias is provided on a peripheral edge of a pad.

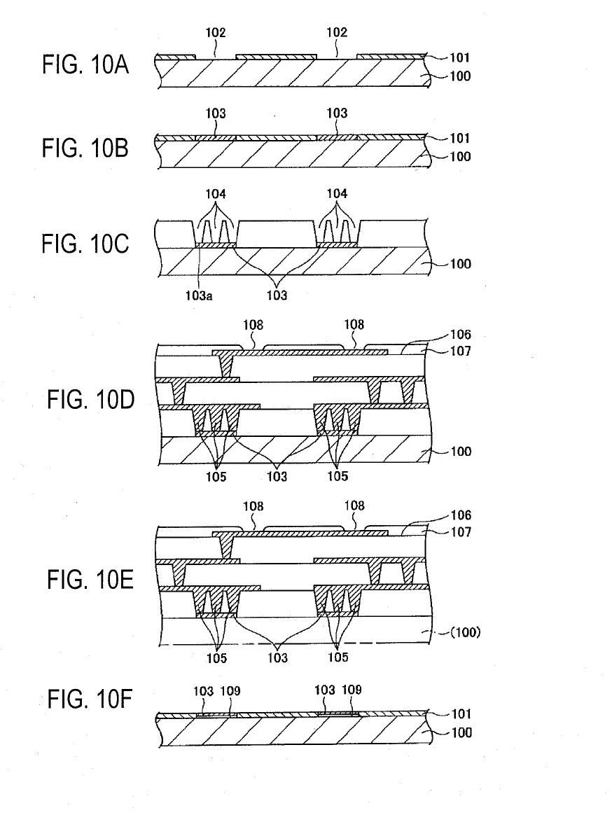

FIG. 9 is a flowchart illustrating a flow of the manufacture of the multilayer wiring board according to the fifth embodiment of the invention. In the manufacture of the multilayer wiring board, it is possible to utilize a method of stacking using a buildup board. Each stage of the manufacturing flow is constituted by (1) a preparation, (2) a formation of a pad, (3) a formation of a connecting via and a stack, (4) a treatment for a board surface, and (5) a removal of a support board and finishing.

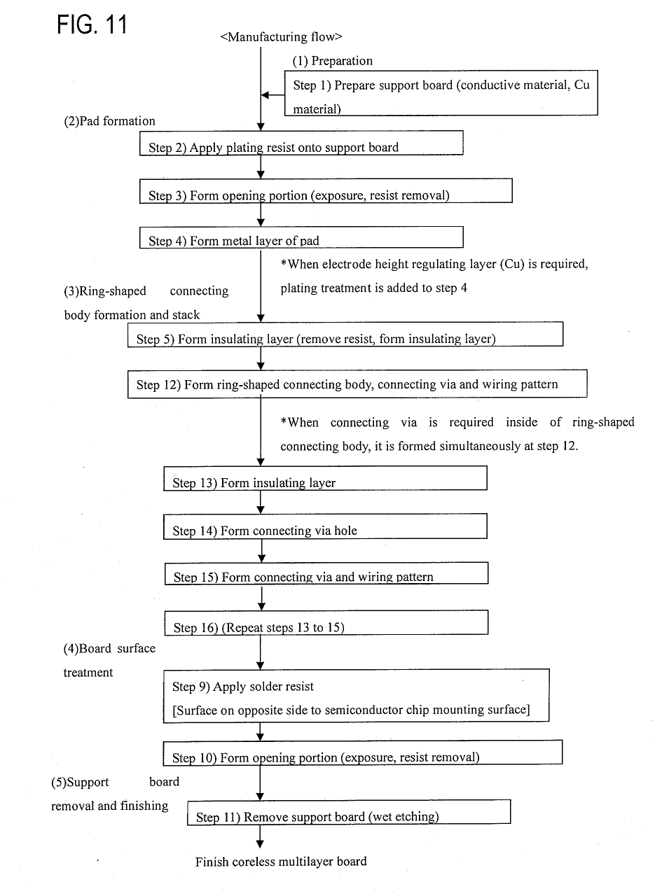

FIGS. 10A to 10F are views illustrating a state of a middle step in the manufacture of the multilayer wiring board. With reference to each drawing of FIGS. 10A to 10F, description will be given to each step in the flow of the manufacture of the multilayer wiring board according to the fifth embodiment of the invention.

In the stage of (1), a support board 100 to be a conductive material such as a copper plate is prepared.

In the stage of (2), a plating resist 101 is formed on the support board 100 shown in FIG. 10A through a film lamination or screen printing coating in order to form a pad at a step 2), a space 102 for forming the pad is provided through an exposure and development at a step 3), a metal layer of a pad 103 shown in FIG. 10B is formed by electrolytic plating at a step 4). For example, a surface to be bonded to a metal bump (not shown) is formed of gold or nickel and a pad body is thus formed of copper. In the case in which a position of a surface of the pad is set to a side of an inner layer from a position of a surface of an insulating layer (described in the variant 2 of the first embodiment), it is preferable to carry out copper plating as an electrode height regulating layer before plating for the surface at the step 4).

FIG. 10F illustrates an electrode height regulating layer 109 and the pad 103.

In the stage of (3), the plating resist is removed and an insulating layer such as an epoxy resin is then formed at a step 5), a connecting via space 104 is formed by a laser as shown in FIG. 10C at a step 6), and a formation of a seed layer, plating resist coating and patterning are thereafter carried out as a formation of a wiring pattern at a step 7). Furthermore, the steps 5) to 7) in the stage (3) of FIG. 9 are repeated depending on the number of stacked layers in the multilayer wiring board so that a multilayer wiring shown in FIG. 10D is formed.

In FIGS. 10C and 10D, it is particularly important to maintain precision in a position of a perforation when forming the connecting via space 104 for connecting a connecting via 105 to a peripheral edge 103a of the pad 103. The reason is as follows. In the case in which a perforating position gets out of the peripheral edge of the pad, a failure is caused in a connecting part of the peripheral edge of the pad and the connecting via, resulting in an occurrence of peeling of the insulating layer from the pad metal or a crack at a next via and patterning forming step.

In the stage of (4), a solder resist 107 is applied onto a surface 106 at an opposite side to a semiconductor chip mounting surface in FIG. 10D to form another opening portion 108.

In the stage of (5), as shown in FIG. 10E, the support board 100 is removed by wet etching so that a coreless multilayer board is finished. In the case in which a position of the surface of the pad is set into a side of an inner layer from a position of the surface of the insulating layer (described in the variant 2 of the first embodiment), it is preferable to remove, through wet etching, copper plating to be the electrode height regulating layer 109 in FIG. 10F which has been applied at the step 4).

### Sixth Embodiment

A sixth embodiment according to the invention illustrates a method of manufacturing a multilayer wiring board in which a ring-shaped connecting body is provided on a peripheral edge of a pad.

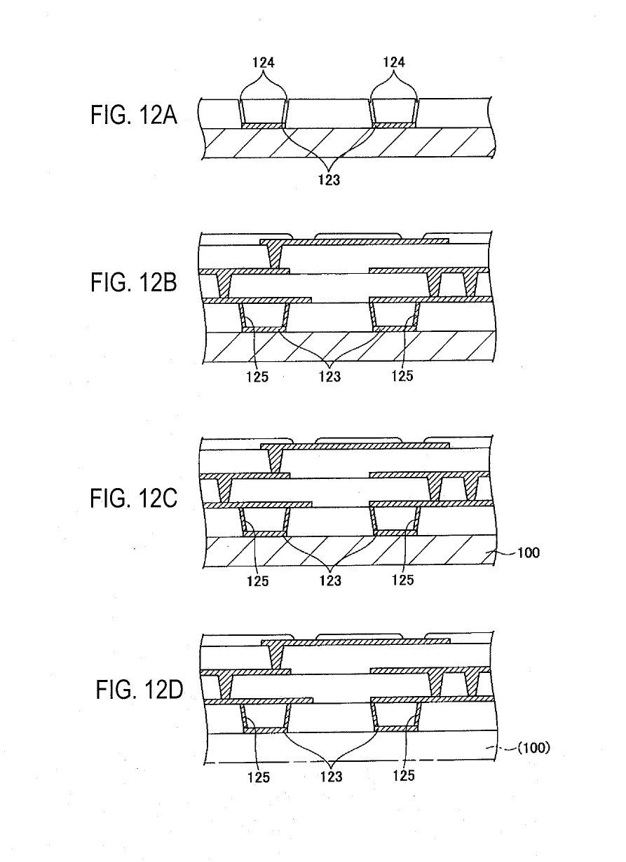

FIG. 11 is a flowchart illustrating a flow of a manufacture of the multilayer wiring board according to the sixth embodiment of the invention. In the manufacture of the multilayer wiring board, it is possible to utilize a method of stacking using a buildup board. Each stage of the manufacturing flow is constituted by (1) a preparation, (2) a formation of a pad, (3) a formation of a ring-shaped connecting body and a stack, (4) a treatment for a board surface, and (5) a removal of a support board and finishing. In the description of (the fifth embodiment), it is possible to obtain a method of manufacturing a multilayer wiring board which is characterized by a ring-shaped connecting body by replacing a portion of “the connecting via” in the sentence of “the connecting via connected to the pad” with “the ring-shaped connecting body”. Since the same portions as those in the description of (the fifth embodiment) are repeated, therefore, description will be omitted.

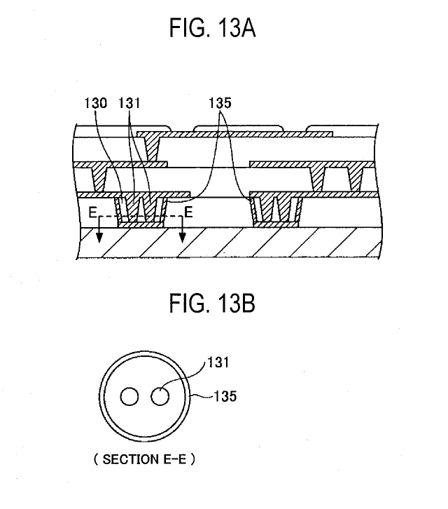

FIGS. 12A to 12D are views illustrating a state of a middle step in the manufacture of the multilayer wiring board. With reference to FIGS. 12A to 12D, description will be given to characteristic steps of the flow of the manufacture of the multilayer wiring board according to the invention in FIG. 11.

In the stage of (3) in FIG. 11, a plating resist is removed and an insulating layer such as an epoxy resin is then formed at a step 5), and a space 124 of a ring-shaped connecting body is formed through a laser as shown in FIG. 12A and a formation of a seed layer, plating resist coating and patterning are then carried out at a step 12). Consequently, a ring-shaped connecting body 125 connected to a pad 123 shown in FIG. 12B is formed. Furthermore, steps 13) to 15) in the stage of (3) in FIG. 11 are repeated depending on the number of stacked layers in the multilayer wiring board.

In the invention, it is particularly important to ensure precision in a position of a perforation when forming the space 124 for the ring-shaped connecting body 125 to be provided on a peripheral edge of the pad 123 in FIGS. 12A and 12B. The reason is that a failure is caused in a connecting portion of the peripheral edge of the pad and the ring-shaped connecting body, resulting in an occurrence of peeling of the insulating layer from the metal of the pad or a crack in the same manner as in the description of (the fifth embodiment).

In the stages of (4) and (5), in the same manner as in the case of the (fifth embodiment), a coreless multilayer board is finished as shown in FIG. 12D via a stacking state in FIG. 12C.

### Variant of Sixth Embodiment

A variant of a sixth embodiment according to the invention illustrates a method of manufacturing a multilayer wiring board in which a connecting via is provided in a space formed by a ring-shaped connecting body in addition to the ring-shaped connecting body.

FIG. 13A is a view illustrating a multilayer wiring board in a state in which two connecting vias 131 are provided in a space 130 formed by a ring-shaped connecting body 135 in relation to the manufacturing method.

FIG. 13B is a sectional view taken along a cutting line E-E in FIG. 13A.

It is possible to carry out a method of manufacturing the multilayer wiring board having the structure by forming a hole for a connecting via when forming a space for a ring-shaped connecting body and performing a plating treatment at the same time at the step 12) in the flow for manufacturing the ring-shaped connecting body shown in FIG. 11.

Although the preferred embodiments according to the invention have been described above in detail, the invention is not restricted to the embodiments but various modifications and changes can be made to the embodiments without departing from the scope of the invention.

For example, although the multilayer wiring board including a “coreless board”, that is, no core board which has a reinforcing and supporting function of a stacked element of the multilayer wiring board has been described in the invention, the invention is not restricted to the coreless board but it is possible to improve a reliability of a product and to enhance quality by utilizing the technique of the invention also in a multilayer wiring board having the core board.

What is claimed is:

1. A multilayer wiring board comprising:
a wiring layer;
a pad;
an insulating layer provided between the wiring layer and the pad; and
a plurality of connecting vias provided on the insulating layer and connecting the wiring layer to the pad,
wherein the connecting vias are provided on a peripheral edge of the pad.

2. The multilayer wiring board according to claim 1, wherein the connecting vias have sectional areas on the respective wiring layer sides which are larger than sectional areas on the pad side.

3. A multilayer wiring board comprising:
a wiring layer;
a pad;
an insulating layer provided between the wiring layer and the pad; and
a ring-shaped connecting body provided on the insulating layer and connecting the wiring layer to the pad,
wherein the ring-shaped connecting body is provided on a peripheral edge of the pad.

4. The multilayer wiring board according to claim 3, further comprising:
a connecting via provided on the insulating layer at an inside of the ring-shaped connecting body and connecting the wiring layer to the pad.

5. The multilayer wiring board according to claim 1, wherein a surface of the pad on an opposite side to a side where the connecting via is provided is flat.

6. The multilayer wiring board according to claim 3, wherein a surface of the pad on an opposite side to a side where the ring-shaped connecting body is provided is flat.

7. The multilayer wiring board according to claim 1, wherein the multilayer wiring board is a coreless board.

8. The multilayer wiring board according to claim 3, wherein the multilayer wiring board is a coreless board.

9. A semiconductor package wherein a semiconductor chip or a semiconductor device is provided on the pad of the multilayer wiring board according to claim 1.

10. A semiconductor package wherein a semiconductor chip or a semiconductor device is provided on the pad of the multilayer wiring board according to claim 3.

11. A method of manufacturing a multilayer wiring board, the method comprising steps of:
forming a pad on a support board;
forming an insulating layer on a surface of the support board on which the pad is formed;
forming, in the insulating layer, a space for a plurality of connecting vias to be connected at a peripheral edge of the pad;
forming the connecting vias in the space of the insulating layer;
forming a wiring layer on the insulating layer so that the wiring layer connects to the pad through the connecting vias;
sequentially stacking an insulating layer and a wiring layer into a multilayer on a surface of the insulating layer on which the wiring layer connecting to the pad is formed; and
removing the support board.

12. A method of manufacturing a multilayer wiring board, the method comprising steps of:
forming a pad on a support board;
forming an insulating layer on a surface of the support board on which the pad is formed;
forming, in the insulating layer, a space for a ring-shaped connecting body to be connected at a peripheral edge of the pad;
forming the ring-shaped connecting body in the space of the insulating layer;
forming a wiring layer on the insulating layer so that the wiring layer connects to the pad through the ring-shaped connecting body;
sequentially stacking an insulating layer and a wiring layer into a multilayer on a surface of the insulating layer on which the wiring layer connecting to the pad is formed; and
removing the support board.

13. A method of manufacturing a multilayer wiring board, the method comprising steps of:
forming a pad on a support board;
forming an insulating layer on a surface of the support board on which the pad is formed;
forming, in the insulating layer, a space for a ring-shaped connecting body to be connected at a peripheral edge of the pad and a space for a connecting via to be provided at an inside of the ring-shaped connecting body;
forming the ring-shaped connecting body and the connecting via at the same time in the respective spaces;
forming a wiring layer on the insulating layer so that the wiring layer connects to the pad through the ring-shaped connecting body and the connecting via;
sequentially stacking an insulating layer and a wiring layer into a multilayer on a surface of the insulating layer on which the wiring layer connecting to the pad is formed; and
removing the support board.
